(19) United States
(12) Patent Application Publication
(10) Pub. No.: US 2025/0008710 A1
(43) Pub. Date: Jan. 2, 2025

(54) VEHICLE DISPLAY DEVICE

(71) Applicant: Yazaki Corporation, Tokyo (JP)

(72) Inventors: Tomohiro MIYAZAWA, Shizuoka (JP); Naoya IGUCHI, Shizuoka (JP)

(73) Assignee: Yazaki Corporation, Tokyo (JP)

(21) Appl. No.: 18/884,682

(22) Filed: Sep. 13, 2024

Related U.S. Application Data
(63) Continuation of application No. PCT/JP2023/034043, filed on Sep. 20, 2023.

(30) Foreign Application Priority Data
Sep. 29, 2022 (JP) 2022-155881

(51) Int. Cl. H05K 7/20; G02B 27/01; G02F 1/1333

(52) U.S. Cl. CPC H05K 7/20972; G02B 27/0149; G02F 1/133385

(57) ABSTRACT

A vehicle display device includes: a housing; a liquid crystal display element that is housed in the housing; a mirror that is housed in the housing, and reflects display light to a windshield of a vehicle, the display light being output from the liquid crystal display element; a heat conduction member that is disposed to be in contact with either a display surface or a rear surface of the liquid crystal display element, the heat conduction member being transparent and having a plate shape; and heat radiation accelerating means, the housing includes a through-hole that the heat conduction member is insertable into, the heat conduction member pierces through the through-hole, and includes a protrusion that protrudes from the through-hole to an external space of the housing, and the heat radiation accelerating means accelerates heat radiation of the protrusion.

### CROSS-REFERENCE TO RELATED APPLICATION

This application is a continuation application of International Application No. PCT/JP2023/034043 filed on Sep. 20, 2023 which claims the benefit of priority from Japanese Patent Application No. 2022-155881 filed on Sep. 29, 2022 and designating the U.S., the entire contents of which are incorporated herein by reference.

### BACKGROUND OF THE INVENTION

### 1. Field of the Invention

The present invention relates to a vehicle display device.

### 2. Description of the Related Art

Conventionally, a vehicle display device including a liquid crystal display element has been proposed. Japanese Patent Application Laid-open No. 2005-313733 discloses a vehicle display device that includes a crystal heat radiation plate that transmits a display image and is in contact with an emission side polarizing film, and a liquid crystal holding member that is made of a metal material and holds the crystal heat radiation plate, on an optical path of the display image between a liquid crystal cell and a windshield. Japanese Patent Application Laid-open No. 2005-313733 describes that a display can be prevented from being damaged even in a case where the sunlight has entered.

There is still room for improvement in preventing a rise in temperature of the liquid crystal display element. For example, in a configuration where a transparent heat conduction member is in contact with the liquid crystal display element, it is preferable that heat radiation of the heat conduction member can be accelerated.

### SUMMARY OF THE INVENTION

It is an object of the present invention to provide a vehicle display device that can prevent a rise in temperature of the liquid crystal display element.

In order to achieve the above mentioned object, a vehicle display device according to one aspect of the present invention includes: a housing; a liquid crystal display element that is housed in the housing; a mirror that is housed in the housing, and reflects display light to a windshield of a vehicle, the display light being output from the liquid crystal display element; a heat conduction member that is disposed to be in contact with either a display surface or a rear surface of the liquid crystal display element, the heat conduction member being transparent and having a plate shape; and heat radiation accelerating means, wherein the housing includes a through-hole that the heat conduction member is insertable into, the heat conduction member pierces through the through-hole, and includes a protrusion that protrudes from the through-hole to an external space of the housing, and the heat radiation accelerating means accelerates heat radiation of the protrusion.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is a diagram illustrating a vehicle display device according to an embodiment;

FIG. 2 is a diagram explaining a cooling operation of the vehicle display device according to the embodiment;

FIG. 3 is a diagram illustrating heat radiation accelerating means according to the embodiment; and

FIG. 4 is a diagram illustrating heat radiation accelerating means according to a variation of the embodiment.

### DETAILED DESCRIPTION OF THE PREFERRED EMBODIMENTS

A vehicle display device according to an embodiment of the present invention is described in detail below with reference to the drawings. Note that this embodiment is not restrictive of this invention. Furthermore, components in the embodiment described below include components that those skilled in the art could easily conceive of, or substantially the same components.

### Embodiment

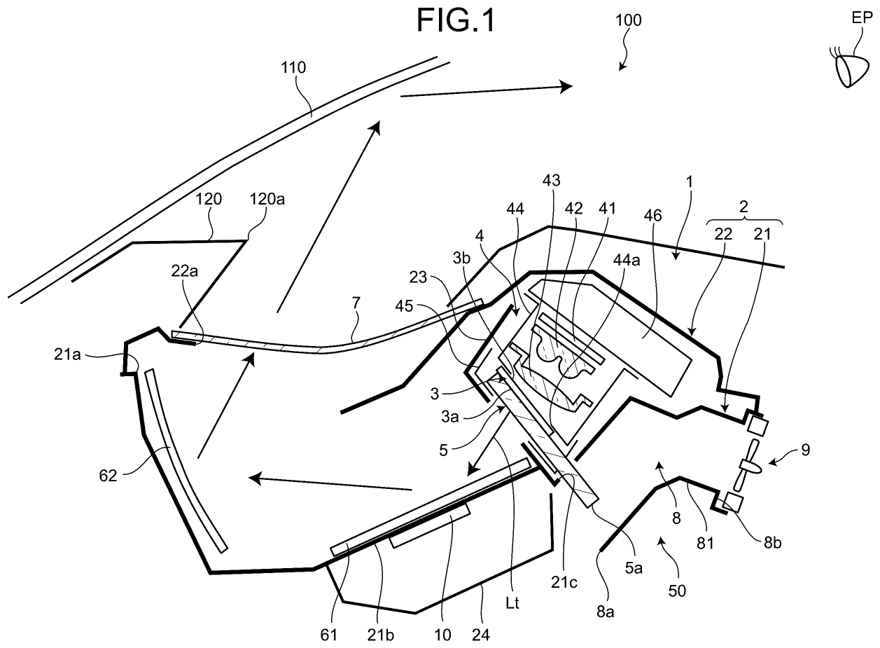

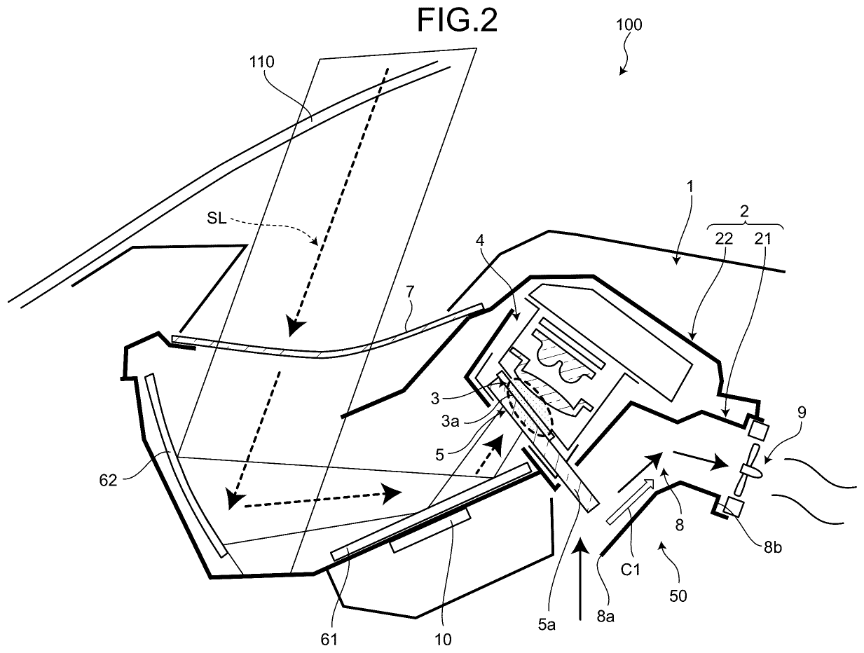

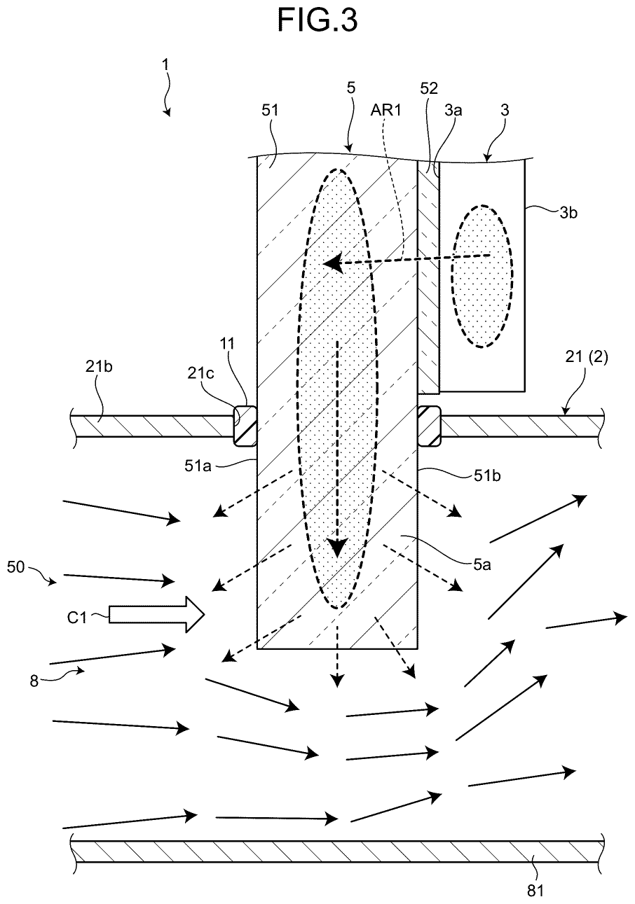

An embodiment is described with reference to FIGS. 1 to 3. The present embodiment relates to a vehicle display device. FIG. 1 is a diagram illustrating the vehicle display device according to the embodiment, FIG. 2 is a diagram explaining a cooling operation of the vehicle display device according to the embodiment, and FIG. 3 is a diagram illustrating heat radiation accelerating means according to the embodiment.

As illustrated in FIG. 1, a vehicle display device 1 according to the present embodiment is mounted on a vehicle 100 such as an automobile. The vehicle display device 1 includes a housing 2, a liquid crystal display element 3, a backlight unit 4, a heat conduction member 5, a first mirror 61, a second mirror 62, a transparent cover 7, a control unit 10, and heat radiation accelerating means 50. The housing 2 is housed below a dashboard 120 of the vehicle 100. The dashboard 120 includes an opening 120a that transmits display light Lt of the vehicle display device 1. The opening 120a faces a windshield 110 in a vehicle upward/downward direction.

The housing 2 is formed of a light shielding material. At least a portion of the housing 2 may be formed of a material having high heat conductivity, such as metal. The housing 2 includes a body 21, an upper cover 22, and a lower cover 24. The body 21 is a box-shaped member including an opening 21a that is open upward. The liquid crystal display element 3, the backlight unit 4, the heat conduction member 5, the first mirror 61, and the second mirror 62 are housed in the body 21, and are fixed to the body 21. The body 21 includes a housing portion 23 that houses the backlight unit 4. A shape of the housing portion 23 is, for example, a tubular shape. A portion of a wall that constitutes the housing portion 23 is a bottom wall 21b. The upper cover 22 is attached to the body 21, and closes the opening 21a of the body 21.

The liquid crystal display element 3 is a display element that includes a liquid crystal that displays an image. The liquid crystal display element 3 is, for example, a thin film transistor-liquid crystal display (TFT-LCD). The liquid crystal display element 3 is, for example, a film-shaped member that includes a liquid crystal layer, a glass electrode, a polarizing plate, or the like. The liquid crystal display element 3 includes a display surface 3a that outputs display light Lt. In the description below, a surface that is opposite to a side of the display surface 3a in the liquid crystal display element 3 is referred to as a rear surface 3b.

The backlight unit 4 applies light to the rear surface 3b of the liquid crystal display element 3. The backlight unit 4 includes a light source 41, a condenser lens 42, a divergent lens 43, a backlight case 44, a bezel 45, and a heat sink 46. The light source 41 includes a plurality of light emitters. The light emitter is, for example, a light-emitting element such as an LED. The condenser lens 42 is a lens that condenses light that has been generated by the light source 41. The divergent lens 43 is a lens that causes the light condensed by the condenser lens 42 to diverge at a desired angle.

The backlight case 44 houses the light source 41, the condenser lens 42, and the divergent lens 43. The backlight case 44 is formed of a light shielding material. A wall surface that faces the divergent lens 43 in the backlight case 44 includes an opening 44a. The backlight case 44 is housed in the housing portion 23 of the housing 2. The heat sink 46 is disposed on a rear surface side relative to the backlight case 44. The heat sink 46 is disposed in such a way that heat generated in the light source 41 can radiate to an outside of the backlight case 44.

The liquid crystal display element 3 is disposed on an outer side relative to the backlight case 44, and faces the opening 44a. Light of the light source 41 passes through the divergent lens 43 and the opening 44a, and enters the rear surface 3b of the liquid crystal display element 3. The bezel 45 is a frame member that holds the liquid crystal display element 3 and the heat conduction member 5 described later. The bezel 45 is fixed to the backlight case 44. The bezel 45 is open in such a way that the display light Lt that has been output from the liquid crystal display element 3 can pass through the bezel 45. Furthermore, the housing portion 23 is open in such a way that the display light Lt that has been output from the liquid crystal display element 3 can pass through the housing portion 23.

The first mirror 61 is a mirror that reflects, to the second mirror 62, the display light Lt that has been output from the liquid crystal display element 3. The illustrated first mirror 61 is disposed on the bottom wall 21b of the housing 2. Cold mirror processing has been performed on a reflecting surface of the first mirror 61. The reflecting surface of the first mirror 61 reflects visible light, and transmits infrared light. The first mirror 61 is, for example, a plane mirror.

The second mirror 62 is a mirror that reflects the display light Lt that has entered from a side of the first mirror 61, to the windshield 110 of the vehicle 100. A shape of a reflecting surface of the second mirror 62 is, for example, a concave free-form surface. The reflecting surface of the second mirror 62 is formed to magnify an image formed by the display light Lt. The upper cover 22 of the housing 2 includes an opening 22a that causes the display light Lt to pass through the upper cover 22. The transparent cover 7 is fixed to the upper cover 22, and closes the opening 22a.

The display light Lt that has been reflected by the second mirror 62 is transmitted through the cover 7, and enters the windshield 110. The windshield 110 reflects the display light Lt toward an eye point EP of the vehicle 100. A driver of the vehicle 100 visually recognizes a virtual image in accordance with the display light Lt that has been reflected by the windshield 110.

The control unit 10 is disposed on the bottom wall 21b of the housing 2. The control unit 10 is configured to control the liquid crystal display element 3 and the backlight unit 4. The control unit 10 is further configured to control the fan 9 described later. The control unit 10 is, for example, a computer that includes an arithmetic circuit, a memory, and a communication interface. The control unit 10 may be disposed on a control board. The illustrated control unit 10 is disposed on an outside surface of the bottom wall 21b. The lower cover 24 engages with the bottom wall 21b of the body 21, and covers the control unit 10.

The vehicle display device 1 according to the present embodiment is configured to cool down the liquid crystal display element 3 in such a way that the liquid crystal display element 3 can be protected from heat, as described below. A cooling structure that cools down the liquid crystal display element 3 includes the heat conduction member 5 and the heat radiation accelerating means 50. The heat radiation accelerating means 50 is configured to accelerate heat radiation of the heat conduction member 5, and includes a flow passage 8 and the fan 9.

The heat conduction member 5 is a transparent member, and can transmit the display light Lt. A shape of the illustrated heat conduction member 5 is a flat plate shape. The heat conduction member 5 has heat conductivity that is higher than at least heat conductivity of air. The heat conduction member 5 is formed of, for example, sapphire glass. The heat conduction member 5 is disposed to be in contact with the display surface 3a of the liquid crystal display element 3. It is desirable that an area of contact of the heat conduction member 5 with the liquid crystal display element 3 have a large value. The heat conduction member 5 according to the present embodiment is in contact with the entire surface of the display surface 3a. It is preferable that the heat conduction member 5 cover the entirety of an image display region in the liquid crystal display element 3.

A thickness of the heat conduction member 5 may be greater than a thickness of the liquid crystal display element 3. The heat conduction member 5 that is in contact with the liquid crystal display element 3 can increase the heat capacity of the liquid crystal display element 3. The heat conduction member 5 absorbs the heat of the liquid crystal display element 3, and can prevent a rise in temperature of the liquid crystal display element 3.

The heat conduction member 5 according to the present embodiment is formed in such a way that a portion of the heat conduction member 5 can protrude to an external space of the housing 2. The heat conduction member 5 extends toward the bottom wall 21b along the display surface 3a of the liquid crystal display element 3. The bezel 45 of the backlight unit 4 is configured to cause the heat conduction member 5 to pierce through the bezel 45. The bottom wall 21b of the housing 2 includes a through-hole 21c that the heat conduction member 5 can be inserted into. The through-hole 21c causes an internal space of the housing 2 to communicate with the external space of the housing 2. The heat conduction member 5 pierces through the through-hole 21c. The heat conduction member 5 includes a protrusion 5a that protrudes from the through-hole 21c to the external space of the housing 2. The protrusion 5a protrudes, for example, downward from the through-hole 21c. The heat conduction member 5 can radiate the heat of the liquid crystal display element 3 to the external space of the housing 2.

The heat radiation accelerating means 50 includes the flow passage 8 and the fan 9. The flow passage 8 is formed outside the housing 2 relative to the bottom wall 21b. The flow passage 8 is formed by the outside surface of the bottom wall 21b and a wall 81. The wall 81 has a semi-cylindrical shape, and forms the flow passage 8 having a tunnel shape.

The protrusion 5a protrudes to the flow passage 8, and crosses a flow direction of air in the flow passage 8. The illustrated protrusion 5a is disposed at an inlet 8a of the flow passage 8. The fan 9 generates an air flow in the flow passage 8. The illustrated fan 9 is disposed at an outlet 8b of the flow passage 8. A rotation direction of the fan 9 is a direction in which the air of the flow passage 8 is discharged from the flow passage 8. Stated another way, the fan 9 rotates to generate an air flow from the inlet 8a to the outlet 8b.

FIG. 2 illustrates a state at a cooling time of cooling down the liquid crystal display element 3. FIG. 2 illustrates external light SL that enters an inside of the housing 2. The external light SL is, for example, sunlight that is transmitted through the windshield 110 into a vehicle cabin. The external light SL illustrated in FIG. 2 is transmitted through the cover 7, and is reflected to the liquid crystal display element 3 by the second mirror 62 and the first mirror 61. The external light SL raises the temperature of the liquid crystal display element 3. In a case where the second mirror 62 is a magnifying mirror, the external light SL is condensed by the second mirror 62, and therefore the temperature of the liquid crystal display element 3 is likely to rise.

The fan 9 according to the present embodiment may be controlled by the control unit 10. In this case, the control unit 10 may rotate the fan 9 on the basis of the temperature of the liquid crystal display element 3. The temperature of the liquid crystal display element 3 may be detected by a temperature sensor. The control unit 10 may rotate the fan 9 in a case where the external light SL has entered the inside of the housing 2. In this case, the control unit 10 may acquire a detection result from an optical sensor that is disposed inside the housing 2. Note that the control unit 10 may rotate the fan 9 in a case where a power source of the vehicle display device 1 is in an ON state.

If the fan 9 has rotated, external air flows into the flow passage 8 from the inlet 8a, as illustrated in FIG. 2. The fan 9 generates an air flow C1 inside the flow passage 8. The air to be introduced to the flow passage 8 may be air that has been cooled down by an air conditioner. The air that flows the flow passage 8 accelerates heat radiation of the protrusion 5a of the heat conduction member 5. The air that has absorbed heat from the protrusion 5a is discharged from the flow passage 8 by the fan 9. The illustrated fan 9 discharges the air backward in a vehicle forward/backward direction.

As illustrated in FIG. 3, the heat conduction member 5 according to the present embodiment includes the body 51 and a transparent adhesive sheet 52. The body 51 is a plate-shaped member that is formed of sapphire glass or the like, and includes the protrusion 5a. The adhesive sheet 52 is a film-shaped member, and causes the body 51 to adhere to the display surface 3a of the liquid crystal display element 3. As illustrated as arrow AR1, the heat of the liquid crystal display element 3 is transferred to the body 51 via the adhesive sheet 52.

The air flow C1 of the flow passage 8 cools down the protrusion 5a of the heat conduction member 5, and accelerates heat radiation of the protrusion 5a. The illustrated protrusion 5a is disposed in such a way that a single principal face 51a faces the air flow C1. The principal face 51a is one of two principal faces 51a and 51b included in the body 51. Another principal face 51b is a face that adheres to the liquid crystal display element 3 by using the adhesive sheet 52. The principal face 51a faces the air flow C1, and this results in improvements in a cooling effect.

An annular packing 11 is disposed between the through-hole 21c and the heat conduction member 5. The packing 11 airtightly seals a gap between the heat conduction member 5 and the bottom wall 21b. The packing 11 prevents gas from flowing between the internal space of the housing 2 and the flow passage 8. The packing 11 prevents dust or foreign matters from entering the inside of the housing 2 from the flow passage 8. The packing 11 can protect the liquid crystal display element 3 or the mirror 61 or 62 from dust or foreign matters.

Note that the heat conductivity of the packing 11 may be higher than the heat conductivity of air. In this case, the packing 11 can release heat from the heat conduction member 5 to the bottom wall 21b. The bottom wall 21b is cooled down by the air flow C1. Heat is released from the heat conduction member 5 to the bottom wall 21b via the packing 11, and this achieves a cooling effect that is similar to a cooling effect in a case where the surface area of the protrusion 5a is increased.

As described above, the vehicle display device 1 according to the present embodiment includes the housing 2, the liquid crystal display element 3, the second mirror 62, the heat conduction member 5 that is transparent and has a plate shape, and the heat radiation accelerating means 50. The liquid crystal display element 3 is housed in the housing 2. The second mirror 62 is housed in the housing 2, and reflects the display light Lt that has been output from the liquid crystal display element 3, to the windshield 110 of the vehicle 100. The heat conduction member 5 is disposed to be in contact with the display surface 3a of the liquid crystal display element 3.

The housing 2 includes the through-hole 21c that the heat conduction member 5 can be inserted into. The heat conduction member 5 pierces through the through-hole 21c, and protrudes from the through-hole 21c to the external space of the housing 2. The heat radiation accelerating means 50 accelerates heat radiation of the protrusion 5a. The vehicle display device 1 according to the present embodiment includes the protrusion 5a of the heat conduction member 5 that protrudes from the housing 2 to the outside, and accelerates heat radiation of the protrusion 5a by using the heat radiation accelerating means 50. Therefore, the vehicle display device 1 according to the present embodiment can prevent a rise in temperature of the liquid crystal display element 3.

The heat radiation accelerating means 50 according to the present embodiment includes the flow passage 8 that is disposed outside the housing 2, and the fan 9 that generates the air flow C1 in the flow passage 8. The protrusion 5a protrudes to the flow passage 8. The heat radiation accelerating means 50 can forcibly cool down the protrusion 5a by using the air flow C1 generated by the fan 9.

The vehicle display device 1 according to the present embodiment includes the packing 11 that is disposed in the through-hole 21c and airtightly seals a gap between the heat conduction member 5 and the housing 2. The packing 11 can prevent dust or the like from entering the inside of the housing 2.

The vehicle display device 1 may further have a configuration that releases heat from the heat conduction member 5 to the housing 2. In this case, it is preferable that the entirety or a portion of the housing 2 be formed of a material having high heat conductivity, such as metal. The heat conduction member 5 is disposed to be in contact with a portion having high heat conductivity in the housing 2. The heat conduction member 5 may be in direct contact with the housing 2, or may be in contact with the housing 2 with a member having high heat conductivity, such as a heat conduction sheet, interposed therebetween. A portion of contact with the heat conduction member 5 in the housing 2 may be provided with a heat radiation member such as a heat sink. In the heat conduction member 5, an end located on a side that is opposite to a side of the protrusion 5a may be in contact with the housing 2. In this case, both ends of the heat conduction member 5 are cooled down, and this efficiently prevents a rise in temperature of the liquid crystal display element 3.

Note that a method for fixing the body 51 of the heat conduction member 5 to the liquid crystal display element 3 is not limited to adhesive fixing using the adhesive sheet 52. The body 51 and the liquid crystal display element 3 may be pressed against each other by using a spring or a screw. The heat conduction member 5 may be in contact with the rear surface 3b instead of being in contact with the display surface 3a of the liquid crystal display element 3.

A protrusion direction of the protrusion 5a is not limited to a downward direction. For example, the protrusion 5a may protrude toward a side of the housing 2. In this case, a through-hole may be provided on a side wall of the housing 2.

Means for generating the air flow C1 in the flow passage 8 is not limited to the flow passage 8 and the fan 9. A cool blast of an air conditioner may be applied to the protrusion 5a from an air conditioning duct. In this case, the cool blast may be guided from the air conditioning duct to the inlet 8a of the flow passage 8. Traveling wind of the vehicle 100 may be applied to the protrusion 5a. In this case, the inlet 8a of the flow passage 8 may be provided in a position that can receive the traveling wind.

### Variation of Embodiment

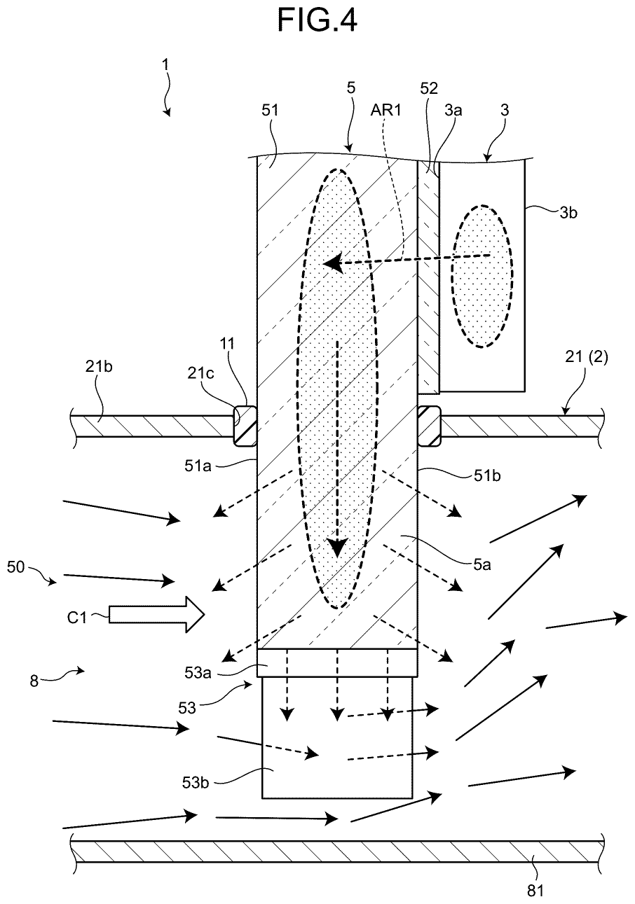

A variation of the embodiment is described with reference to FIG. 4. FIG. 4 is a diagram illustrating heat radiation accelerating means according to the variation of the embodiment. Heat radiation accelerating means 50 according to the variation includes a heat sink 53 that is attached to the protrusion 5a of the heat conduction member 5. The heat sink 53 includes a base 53a that is fixed to the protrusion 5a, and a plurality of fins 53b.

The heat sink 53 is formed of a material having high conductivity, such as metal. The base 53a is in contact with a front end surface of the protrusion 5a. The plurality of fins 53b protrudes from the base 53a to a side that is opposite to a side of the heat conduction member 5. The plurality of fins 53b is disposed in such a way that the air flow C1 can pass among the plurality of fins 53b. The heat sink 53 can accelerate heat radiation of the protrusion 5a.

Note that the flow passage 8 and the fan 9 may be omitted in a case where the heat radiation accelerating means 50 includes the heat sink 53. The heat sink 53 that is disposed outside the housing 2 can accelerate heat radiation of the protrusion 5a. A cool blast of an air conditioner may be applied to the protrusion 5a and the heat sink 53 from an air conditioning duct. Traveling wind of the vehicle 100 may be applied to the protrusion 5a and the heat sink 53.

Pieces of content disclosed in the embodiment and the variation that have been described above can be appropriately combined and implemented.

### Reference Signs List

In the vehicle display device according to the present embodiment, the transparent heat conduction member includes the protrusion that protrudes to the external space of the housing. The heat radiation accelerating means accelerates heat radiation of the protrusion. The vehicle display device according to the present embodiment can exhibit an advantageous effect in which a rise in temperature of the liquid crystal display element can be prevented.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A vehicle display device comprising:
a housing;
a liquid crystal display element that is housed in the housing;
a mirror that is housed in the housing, and reflects display light to a windshield of a vehicle, the display light being output from the liquid crystal display element;
a heat conduction member that is disposed to be in contact with either a display surface or a rear surface of the liquid crystal display element, the heat conduction member being transparent and having a plate shape; and
heat radiation accelerating means, wherein
the housing includes a through-hole that the heat conduction member is insertable into,
the heat conduction member pierces through the through-hole, and includes a protrusion that protrudes from the through-hole to an external space of the housing, and
the heat radiation accelerating means accelerates heat radiation of the protrusion.

2. The vehicle display device according to claim 1, wherein
the heat radiation accelerating means includes a flow passage that is disposed outside the housing, and a fan that generates an air flow in the flow passage, and
the protrusion protrudes to the flow passage.

3. The vehicle display device according to claim 1, wherein
the heat radiation accelerating means includes a heat sink that is disposed to be in contact with the protrusion.

4. The vehicle display device according to claim 1, further comprising:
a packing that is disposed in the through-hole, and airtightly seals a gap between the heat conduction member and the housing.

5. The vehicle display device according to claim 2, further comprising:
a packing that is disposed in the through-hole, and airtightly seals a gap between the heat conduction member and the housing.

6. The vehicle display device according to claim 3, further comprising:
a packing that is disposed in the through-hole, and airtightly seals a gap between the heat conduction member and the housing.
